(19) United States
(12) Patent Application Publication
(10) Pub. No.: US 2007/0284680 A1
(43) Pub. Date: Dec. 13, 2007

(54) METHOD FOR MANUFACTURING SEMICONDUCTOR DEVICE AND SEMICONDUCTOR DEVICE USING THE SAME

(75) Inventors: Akinori HASHIMURA, Hyogo (JP); Hiroyuki FUJITA, Tokyo (JP)

Correspondence Address: PEARNE & GORDON LLP, 1801 EAST 9TH STREET, SUITE 1200, CLEVELAND, OH, 44114-3108, US

(73) Assignees: MATSUSHITA ELECTRIC INDUSTRIAL CO., LTD., Osaka (JP); THE UNIVERSITY OF TOKYO, Tokyo (JP)

(21) Appl. No.: 11/738,208

(22) Filed: Apr. 20, 2007

(30) Foreign Application Priority Data
Apr. 20, 2006 (JP) 2006-116411

(51) Int. Cl. H03H 9/46; H01L 21/3205

(52) U.S. Cl. 257/415; 438/669; 257/E21.294

(57) ABSTRACT

A method for manufacturing a semiconductor device, includes: forming a protrusive portion on a surface of a semiconductor substrate, forming a thin film on the surfaces of the semiconductor substrate and the protrusive portion, applying a resist on a surface of the thin film so that at least an apex of the protrusive portion on which the thin film is formed is exposed, etching the thin film formed on the apex of the protrusive portion which is exposed from the resist to separate a pattern of the thin film into a plurality of patterns of the thin film and removing the resist.

### BACKGROUND OF THE INVENTION

The present invention relates to a method for manufacturing a semiconductor device and the semiconductor device manufactured by using the same, and a micro-device manufactured by using MEMS (Micro Electro Mechanical Systems) technology and its manufacturing method, and more particularly to a manufacturing of an RF-MEMS resonator having electrodes and a gap and a protrusive structure of an RF-MEMS filter.

In present MEMS devices, a structure with electrodes sandwiching a gap in a minute structure is applied to a wide field of devices such as a sensor, an actuator, a switch, a resonator and a filter having a capacitive coupling. Among these devices, in a case that two or more electrodes are arranged in a single protrusive structure, there devices are roughly classified into two kinds of electrode structures, one is a parallel electrode structure in which the electrodes are arranged in a plane with respect to a substrate, and the other is a side electrode structure in which the electrodes are arranged in a plane which is perpendicular to or oblique to the substrate. The methods for making two protrusive structures are different, in the case of the parallel electrode structure, at least two film-deposition steps are required, whereas in the side electrode structure, a single film-deposition step is required to form many electrodes simultaneously so that its manufacturing method is simple.

However, in the case of manufacturing the side electrode structure, it is required that a method for separating a conductive film (electrode film) deposited by the single step into two patterns to form the electrodes. For example, in the method of making an electron gun proposed by Mr. Hashiguchi and Mr. Hara, it was realized that the conductive film was pattern-separated by an etch-back step to form two electrodes (see JP-A-6-310029). In this method, by etching the upper part of the resist covering the conductive film which is stacked on the structure having an inclined face and etching, from above, a desired area of the conductive film can be separated at the upper end since the resist serves as a mask. In this case, in order to pattern the other area such as the other end, only a necessary area must be etched. For this purpose, it is required to protect the area other than an area to be etched by a mask.

To this end, the resist applied onto the entire surface is etched back so that the area to be etched is exposed from the resist. Thereafter, the electrode film in this area is etched to form electrodes. This manufacturing method is shown in FIGS. 6A to 6H.

In this method, as shown in FIG. 6A, a pattern having a triangular section encircled by a (111) plane is formed by anisotropic etching of a silicon substrate 100. The surface of the silicon substrate 100 is thermally oxidized to form an insulating film 101 of a silicon oxide film.

As shown in FIG. 6B, a metallic film 102 such as a tungsten film is deposited on the resultant surface. Thereafter, resist R1 is applied so that a film thickness of the resist R1 is greater than the height of the convex of the triangular section of the silicon substrate 100 (FIG. 6C).

As shown in FIG. 6D, the resist R1 is etched back so that the protrusion of the silicon substrate 100 covered with the insulating film 102 of the silicon oxide film is exposed.

In this state, as shown in FIG. 6E, the metallic film 102 is etched by using the resist R1 as a mask so that the metallic film 102 on the protrusion is separated at the upper end by the first etching step, thereby separated electrodes are formed.

Further, as shown in FIG. 6F, an electrode mask is patterned by the subsequent photolithography to form a resist pattern R2. As shown in FIG. 6G, the metallic film is etched by the second etching step to form the electrode with the other end defined. Finally, as shown in FIG. 6H, the insulating film 101 is locally removed to expose the tip of an electron gun emitting portion, thereby completing a MOS device structure equipped with a side electrode pattern.

However, the step of etching back a sacrificing layer such as the resist in the above conventional electrode manufacturing methods requires a sophisticated etching controlling technique and so cannot assure sufficient pattern accuracy. For example, it is very difficult to form a sacrificing layer mask with the apex being exposed in the protrusive portion having an inclined face. The resist etch-back method, in which the apex is patterned by controlling an etching rate, must have special functions of precise time management and detection of an end point of the etching mounted, in the manufacturing device.

Further, in the conventional manufacturing using the etch-back step, at least two steps for patterning the apex and electrode are required. As a result, the number of manufacturing steps and costs are increased.

### SUMMARY OF THE INVENTION

The present invention has been accomplished in view of the above circumstances. An object of the present invention is to form a pattern with high accuracy and high reliability without using precise time management and a special device.

In order to solve the above problem, the present invention provides a method for manufacturing a semiconductor device comprising:

forming a protrusive portion on a surface of a semiconductor substrate;

forming a thin film on the surfaces of the semiconductor substrate and the protrusive portion;

applying a resist on a surface of the thin film so that at least an apex of the protrusive portion on which the thin film is formed is exposed;

etching the thin film formed on the apex of the protrusive portion which is exposed from the resist to separate a pattern of the thin film into a plurality of patterns of the thin film; and

removing the resist.

In accordance with this configuration, the apex of the protrusive portion can be exposed only by adjusting the thickness (height) of an applied resist so that the electrodes can be easily formed.

Specifically, this invention, in a method for manufacturing a semiconductor device such as an MEMS device having an electrode on an inclined face so as to sandwich a gap, permits mask patterns for the apex of the protrusive portion and the electrode to be simultaneously formed. Since the electrodes can be formed with high accuracy by a simple process, the manufacturing method can be realized at low cost.

Preferably, the method, further comprising:

forming an insulating film on the surface of the protrusive portion,

wherein the protrusive portion has an inclined face;

wherein the thin film is a conductive film; and

wherein the conductive film is formed on the surfaces of the semiconductor substrate and the insulating film formed on the protrusive portion in the forming process of the thin film.

In this configuration, the resist is applied on a rugged surface and the conductive film is etched with a part of the convex area being exposed so that it is separated. Therefore, if the bottom of the convex area is matched with that of the conductive film, the heights of the separated conductive films agree with each other.

Preferably, the separating process includes processes of: patterning the resist to expose a part of the conductive film by photolithography process; and etching the part of the conductive film which is exposed from the resist in the patterning process and an apex part of the conductive film disposed on the apex of the protrusive portion.

In accordance with this configuration, patterning of the conductive film can be realized all at once with high efficiency.

Preferably, the semiconductor substrate is an SOI substrate having a single-crystal silicon layer formed on a surface thereof. The forming process of the protrusive portion includes a process of forming the protrusive portion by anisotropic etching so that a (111) plane of the SOI substrate is remained as the inclined face.

In accordance with this configuration, since the anisotropic etching is adopted so that the etching speed in the (111) plane is slow, using the etching selectivity of the (111) plane, the patterning can be performed with high efficiency and good reproducibility.

Preferably, The method further includes:

forming an embedded insulating layer (BOX layer) on the surface of the semiconductor substrate prior to the forming process of the protrusive portion; and

removing the insulating layer (a first insulating film) between the conductive film and the protrusive portion and the embedded insulating layer (a second insulating film) formed below the protrusive portion.

Preferably, the forming process of the embedded insulating layer includes a process of forming a deep groove from a back face of the semiconductor substrate.

In accordance with this configuration, by removing the embedded insulating film, the hollow structure can be realized with very high efficiency.

Also, by removing the first and second insulating films, the hollow structure can be realized with very high efficiency. Further, if the first and second insulating films are formed of the same material, they can be simultaneously etched. The first and second insulating films may not be formed of the same material as long as they can be etched under the same condition.

Preferably, the embedded insulating film is formed so as to have a step portion at an area on which the protrusive portion is to be formed such that the step portion is higher than other area of the surface of the semiconductor substrate.

In accordance with this configuration, the resist for protruding the apex of the protrusive portion can be made thick so that its uniformity and selectivity can be improved.

Preferably, the forming process of the protrusive portion includes a process of forming a concave portion on an apex plane of the protrusive portion.

In accordance with this configuration, by filling the concave area with the resist, a discontinuous area can be formed so that the pattern-separation can be realized.

Preferably, the apex plane of the protrusive portion has a flat face.

In accordance with this configuration, the pattern structure separated between flat areas can be formed with good controllability.

Preferably, the insulating film is an oxide film which is formed by oxidation of the semiconductor substrate.

In accordance with this configuration, the oxide film having an accurate film thickness can be formed with high efficiency.

Preferably, the oxide film having a thickness of several nms is formed by a chemical reaction of the surface of the semiconductor substrate in substrate cleaning (RCA or SPM cleaning).

In accordance with this configuration, by the oxide film obtained in the cleaning step as the insulating film, the thin oxide film can be easily formed with high efficacy. The “RCA” cleaning is a cleaning technique developed by RCA Corporation which combines SC-1 cleaning (Standard Clean 1) consisting of aqueous ammonia and aqueous hydrogen peroxide for the purpose of removal of particles and SC-2 cleaning (Standard Clean 2) consisting of hydrochloric acid and aqueous hydrogen peroxide for the purpose of removal of metallic impurities. The “SPM” cleaning is a cleaning technique of treatment at a high temperature of 100° C. or more by concentrated sulfuric acid doped with aqueous hydrogen peroxide for the purpose of removal of an organic material.

According to the present invention, there is also provided a semiconductor device formed by the method for manufacturing the semiconductor device, comprising:

an oscillator which is formed to be mechanically oscillatable;

an electrode which is arranged apart by a predetermined interval from the oscillator,

wherein the oscillator serves as an MEMS resonator configured by the protrusive portion.

In accordance with this configuration, a fine and reliable lead-like oscillator can be formed.

Preferably, the oscillator has a triangular section.

In accordance with this configuration, by using the sectional triangle having the (111) plane as one side, the pattern can be formed with high accuracy and good reproducibility.

Preferably, the electrode has a step portion.

Preferably, the oscillator has a square section.

Preferably, the oscillator has at least one groove on an upper face thereof.

In accordance with this configuration, if the upper face is flat so that it is difficult to form a gap (separating area), the groove having a predetermined width is formed and filled with the resist. Thus, the upper gap can be formed with high efficiency.

Namely, the manufacturing method according to the present invention is a method for providing an electrode in a protrusive portion having a gap, comprising: forming an insulating film in the protrusive portion having an inclined face; forming a conductive film on the insulating film; applying a resist to the conductive film so that an thickness of the resist is smaller than the height of the protrusive portion; exposing the apex of the protrusive portion by spin-coating the resist; patterning a mask of the conductive film by exposure and development of the resist; etching the patterned conductive film and the exposed apex; and removing the insulating film.

In accordance with this configuration, using the reproducibility of the film thickness by spin-coating, the gap with high size accuracy can be formed, thereby forming the gap with high accuracy and reliability.

In accordance with the method according to the present invention, there is provided an MEMS device which makes unnecessary the etch-back step of the resist whose control is difficult, and can simultaneously form, by a single etching step, the apex and electrode, which was conventionally impossible. Therefore, the manufacturing method capable of forming the apex and a large number of electrodes simply and accurately can be realized. This manufacturing method can be applied to various MEMS devices which form the electrodes through the gap.

### BRIEF DESCRIPTION OF THE DRAWINGS

The above objects and advantages of the present invention will become more apparent by describing in detail preferred exemplary embodiments thereof with reference to the accompanying drawings, wherein:

FIGS. 1A to 1F are sectional explanation views showing the manufacturing steps of an MEMS resonator according to the first embodiment of the present invention;

FIGS. 2A and 2B are views of a triangular sectional beam in the MEMS resonator according to the first embodiment of the present invention;

FIG. 3 is a view of an MEMS resonator according to the first embodiment of the present invention;

FIGS. 4A to 4F are sectional explanation views showing the manufacturing steps of an MEMS resonator having a nanometer size according to the second embodiment of the present invention;

FIGS. 5A to 5J are sectional explanation views showing the manufacturing steps of an MEMS device according to the third embodiment of the present invention; and

FIGS. 6A to 6H are sectional explanation views showing the manufacturing steps of an electron gun manufactured by conventional etch-back steps.

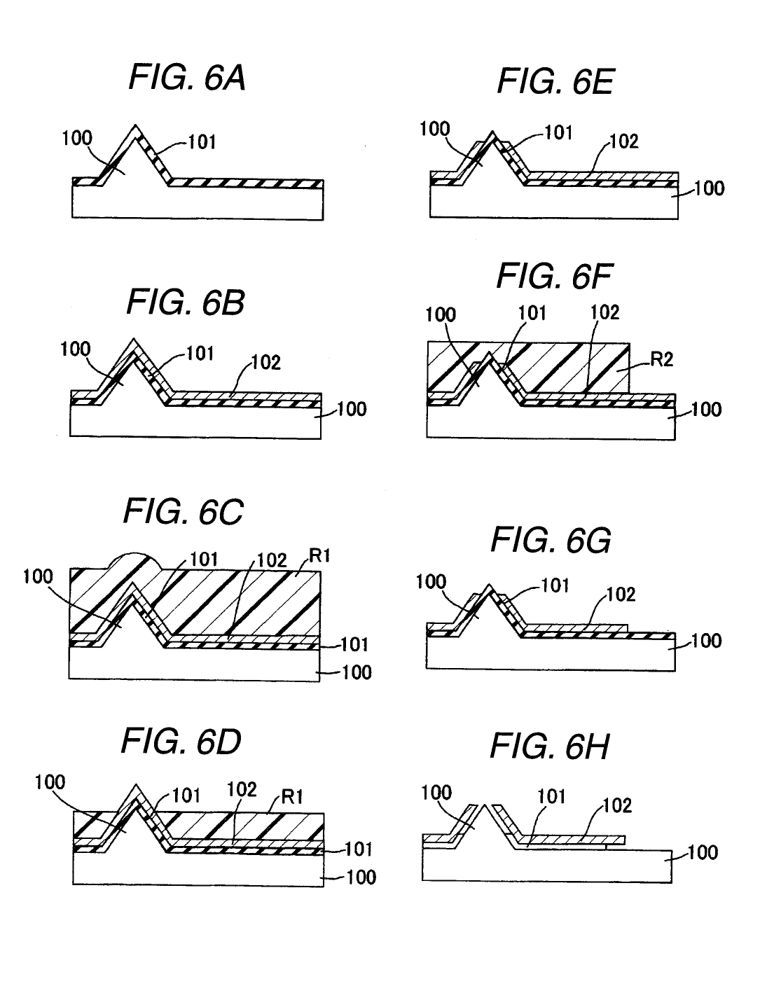

### DETAILED DESCRIPTION OF THE PREFERRED EMBODIMENTS

Now referring to the drawings, an explanation will be given of various embodiments of the present invention.

### Embodiment 1

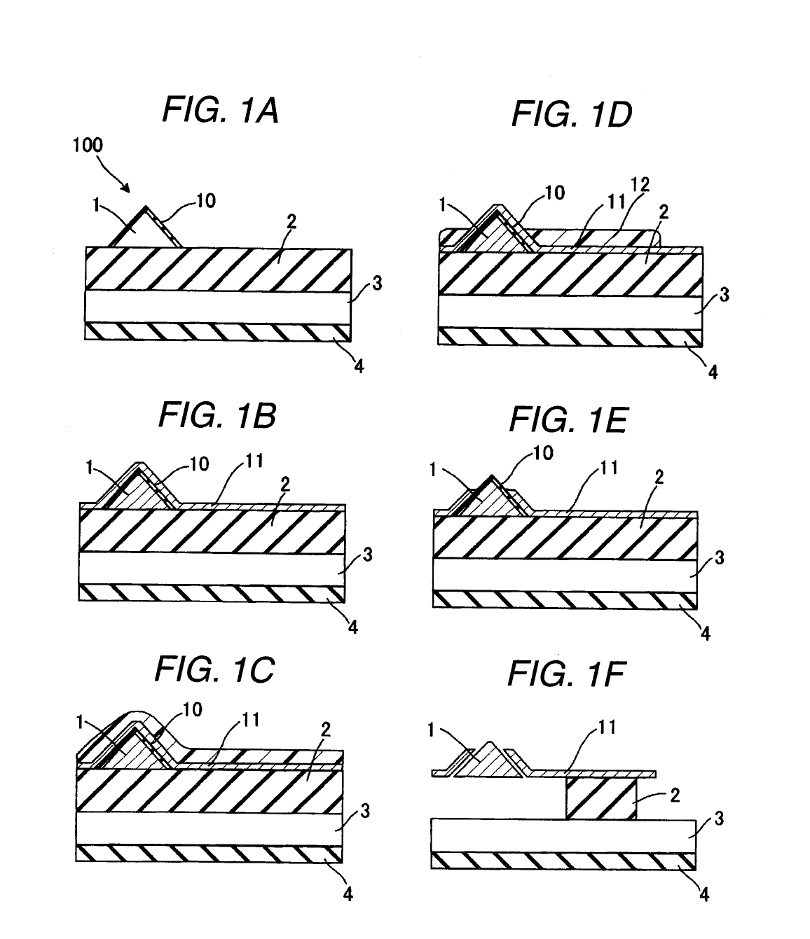

FIGS. 1A to 1F a sectional views showing a manufacturing method according to the first embodiment and an MEMS device manufactured by this method.

The electrode forming method in a microscopic protrusive portion according to the present invention is mainly applicable to forming an MEMS resonator. In the electrode forming method according to this embodiment, first, as shown in FIG. 1A, a triangular sectional beam 1 is formed by anisotropic etching of a single-crystal silicon layer of an SOI substrate. Also, a thin insulating film 10 is formed by thermal oxidation of a surface of the triangular sectional beam 1. In the case of using the SOI substrate, since a BOX layer 2 is formed of an oxide film, the silicon oxide film which is same in material as the BOX layer 2 is used as the insulating layer 10 preferably. This insulating film 10 constitutes a narrow gap of the MEMS resonator which requires to have a thickness of several tens nm to several hundreds nm. The insulating film 10 is preferably an LPCVD oxide film or thermally oxidized film whose thickness can be controlled accurately.

In this way, the structure of the resonator can be obtained by forming the triangular sectional beam 1 through crystal anisotropic etching using a tetramethylammonium hydroxide (TMAH) water solution. At this time, for example, by anisotropic etching of an SOI substrate with a silicon layer having a thickness of 1.5 μm, the silicon is etched along a (111) side plane to etch the triangular section beam with an angle of 54.7° from a silicon surface. Thus, since the width (2.1 μm) of the beam is determined by the thickness of the substrate for manufacture, a beam-type oscillator can be formed with high accuracy.

After the beam-type oscillator having the triangular sectional beam is formed in this way, an oxide film for forming a gap is formed. Since the gap width is related with the RF characteristic of the resonator, the oxide film employed in this case is preferably a uniform and thin film. For example, in a case that the thermally oxidized film is employed as a sacrificing layer, an oxide film having a thickness of 50 nm is grown on the side of the triangular sectional beam in an oxidizing furnace. Thereafter, by the LPCVD method, a doped poly-silicon (conductive film) constituting an electrode film is deposited.

Incidentally, in the manufacturing method according to the present invention, in order to make a narrower gap, an oxide film having a thickness of several nms which gives a silicon surface of the triangular sectional beam 1 by a chemical reaction through a treating step of substrate cleaning (RCA, SPM) required before the step of FIG. 1B may be employed as the above insulating film 10.

Next, the steps of exposing the apex of the triangular sectional beam and forming the mask pattern of the electrode will be performed by photolithography steps. Their details will be explained below.

A positive type resist (Shipley 1805;®) is used as a resist. Using a spin coater, coating is performed with the number of revolutions of 4000 rpm for 30 seconds. Thereafter, using a hot plate at 90° C., baking is performed for about two minutes so that the resist is coated with its uniform thickness (410 nm) being kept so as to give a flat surface on the entire substrate. Since the height of the triangular sectional beam is determined by the thickness (1500 nm) of the silicon layer of the SOI substrate, there is less variations. Thus, the apex (1090 nm) of the beam can be exposed with high accuracy.

Specifically, a conductive film 11 is uniformly deposited by CVD method or the like as shown in FIG. 1B, and a resist 12 is deposited as shown in FIG. 1C. The conductive film 11 is preferably made of poly-silicon. FIG. 1C illustrates the state where the resist 12 applied on the conductive film 11 has been spin-coated. In this state, the apex of the conductive film 11 is exposed. Namely, the number of revolutions of the spinner and the viscosity of the resist are determined so that the thickness of the applied resist is thinner than the height of the triangular sectional beam 1. The resist is spin-coated to determine the thickness of the resist 12. In this case, although it depends on the area to be exposed, if mainly, the film thickness of the resist 12 is ⅓ to ¼ of the height of the triangular sectional beam 1, an apex 13 is exposed after spin-coating is performed. Thereafter, returning to a conventional photolithography step of the conductive film 11, the resist is subjected to exposure and development, thereby patterning the electrode mask.

Further, as shown in FIG. 1D, photolithography is executed to pattern the conductive film 11.

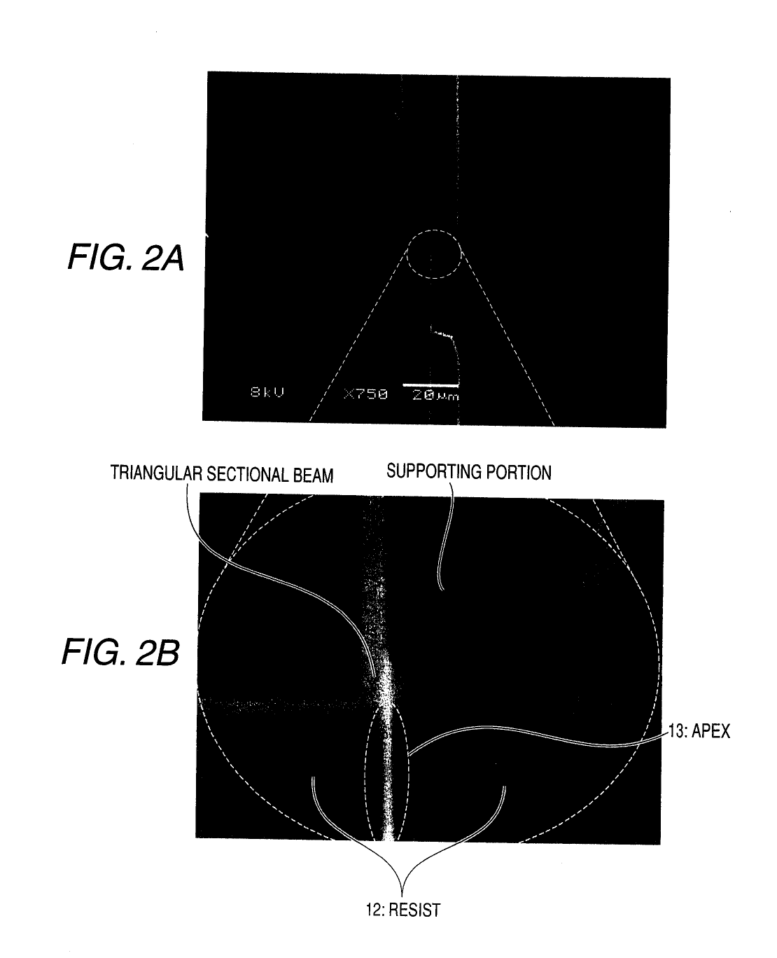

In this way, after exposure of the apex by spin-coating, a photo-mask is formed. The resist is exposed and thereafter developed to form a mask pattern for forming an electrode pattern. The state after this step is shown by SEM photographs of FIGS. 2A and 2B. FIGS. 2A and 2B are an entire view of the triangular sectional beam having a length of 20 μm and a width of 2 μm and its enlarged view, respectively. From these photographs, it can be confirmed that the apex of the beam is exposed with high accuracy and the mask pattern for forming the desired electrode pattern is formed.

Next, as shown in FIG. 1E, the protruded apex 13 and the conductive film 11 which is exposed from the resist patterned by the exposure are simultaneously patterned by a single etching step. Since the etching step is required to adopt an etching condition with good selectivity of the poly-silicon film mainly constituting the conductive film 11 for the oxide film constituting the insulating film 10, dry etching using SF₆ gas is preferably employed in this manufacturing method.

In this way, the exposed apex and electrode are dry-etched by using an RIE device, and thereafter, the resist is completely removed from the substrate.

Next, as shown in FIG. 1F, with a region serving as a support being left, the insulating film 10 and BOX layer 2 are removed to open the triangular sectional beam 1. Thus, a hollow-protrusive portion is completed in which the electrodes having a narrow gap are arranged on the side of the protrusive portion.

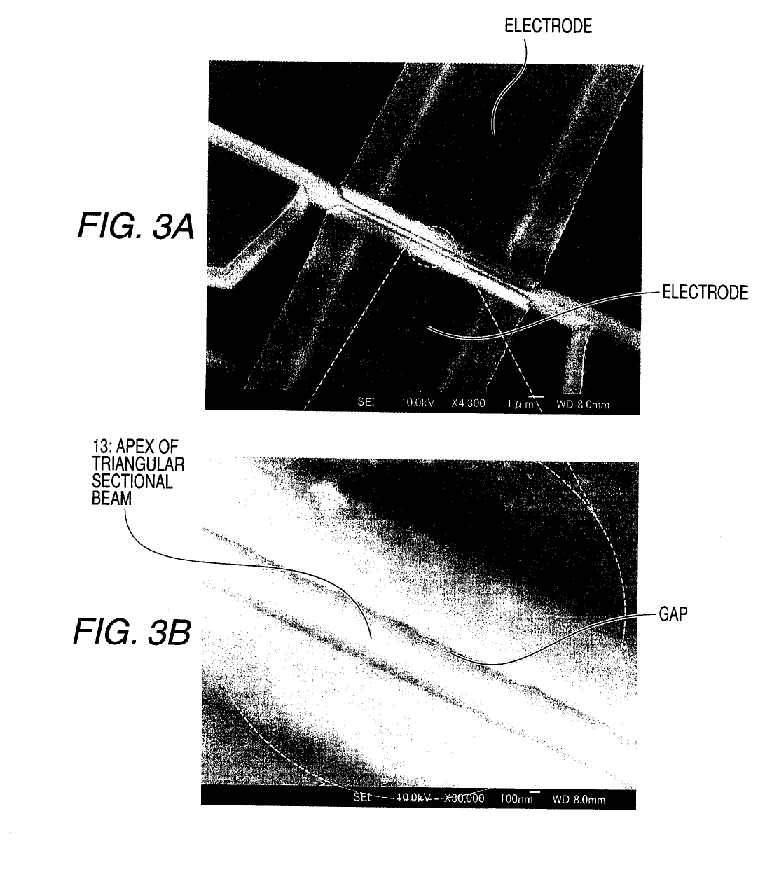

In a final step, since a forming of the gap and an opening of the triangular section beam from the substrate are required, the oxide film between the electrodes and the beam and the oxide film existing in a low layer portion of the beam are removed by using hydrofluoric acid, thereby making the beam-type resonator. The manufactured resonator is shown in FIG. 3.

FIG. 3 shows the structure of the resonator equipped with electrodes on both sides of the triangular sectional beam having a length of 20 μm and a width of 2 μm. It can be confirmed from the photograph that the region between the electrodes and the beam is formed with a narrow gap of 50 nm and the apex of the silicon beam is completely exposed.

Thus, as compared with the conventional electrode forming method using the etch-back step, the electrode pattern can be formed with high accuracy and a less number of steps.

### Embodiment 2

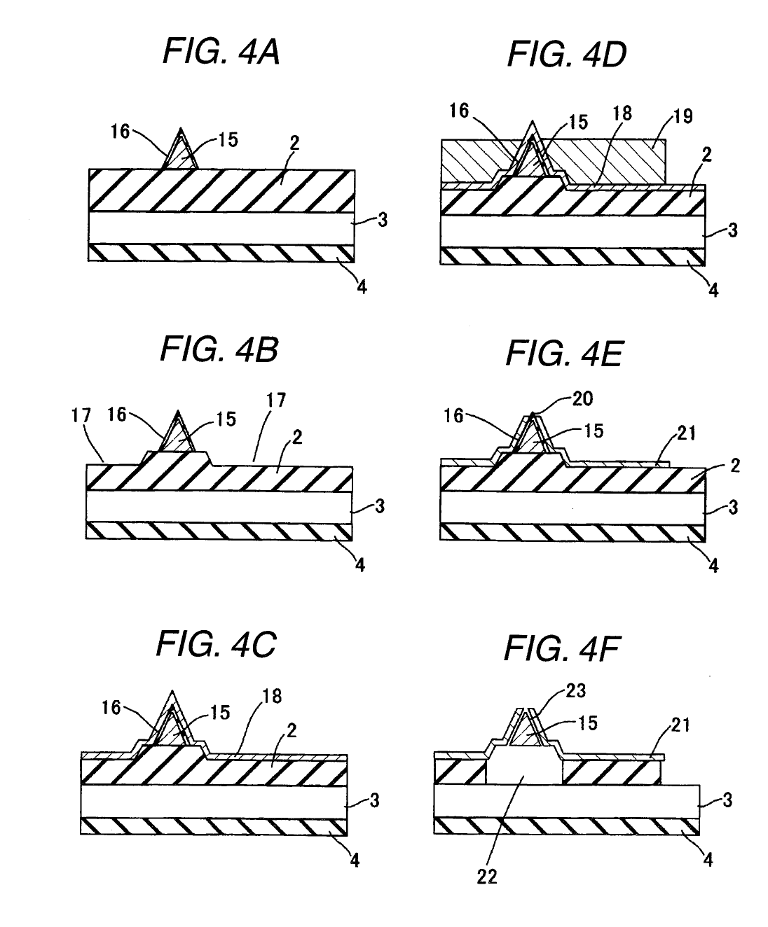

FIGS. 4A to 4F are sectional views showing a manufacturing method according to the second embodiment and an MEMS device manufactured by this method. The feature of the manufacturing method according to this embodiment resides in that the etch-back step is not required. In this method, a groove 17 is formed in the BOX layer 2 to provide a level difference (step) and the height of a triangular sectional beam 15 constructed by the protrusive portion is 1 μm or less. In order to expose the apex at a desired position, the resist 19 to be applied in the subsequent step must be a very thin film. If the thickness of the resist 19 is about ¼ of the height of the triangular sectional beam 19, the thin film having a thickness of 250 nm or less will be applied. This thickness, as the case may be, cannot give uniformity of the resist 19 and selectivity thereof for the electrode to be etched.

In accordance with the present invention, the feature is to form the groove 17 in the BOX layer to provide the level difference. Thus, the resist 19 can be made thick in order to protrude the apex of a nano-protrusive portion 15, thereby improving uniformity and selectivity and also removing necessity of using a special thin film resist.

The method of the nano-protrusive portion forming the electrode according to the present invention is mainly applied to making the MEMS resonator. First, the single-crystal layer on the surface of an SOI substrate 100 is patterned by anisotropic etching to form a triangular sectional beam 15 having a width of 1 μm or less. The SOI substrate 100 is configured by a BOX layer 2, a silicon supporting substrate 3 and a protecting film 4 on a rear surface of the silicon supporting substrate 3 which are stacked. By thermal oxidation of the surface, an insulating film (silicon oxide film) 16 is deposited on the beam 15.

Next, as shown in FIG. 4B, by using the insulating film 16 as a mask, the BOX layer 2 is etched to form the groove 17. Although the depth is adjusted by the thickness of the resist in the subsequent step, the etching is performed within a range of several hundreds nm to several μm. After the groove 17 is formed as shown in FIG. 4B, a conductive film 18 is deposited on the BOX layer 2 and the triangular sectional beam 15 configured by the protrusive portion as shown in FIG. 4C.

As shown in FIG. 4D, a resist 19 is applied and the mask for the apex and electrode is patterned. First, the resist 19 is applied on the conductive film 18. The thickness of the conductive film 18 is set to be equal to or greater than the depth of the groove 17 and not greater than the height of the triangular sectional beam 15 configured by the protrusive portion. Since the groove 17 is formed, the film thickness of the resist can be made thick. In this way, after application of the resist, alignment, exposure and development of the electrode are performed to form the pattern of the electrode mask in a state that the apex of the triangular sectional beam 15 configured by the protrusive structure is protruded.

Next, as shown in FIG. 4E, patterns of the conductive film at an apex 20 and of the conductive film on a periphery 21 are formed. This is characterized in that these patterns are formed by performing the single etching step. Finally, as shown in FIG. 4F, the BOX layer 2 and the insulating layer 16 are removed to form an open portion 22 of the BOX layer and a gap 23, thereby completing an hollow structure of the MEMS resonator.

### Embodiment 3

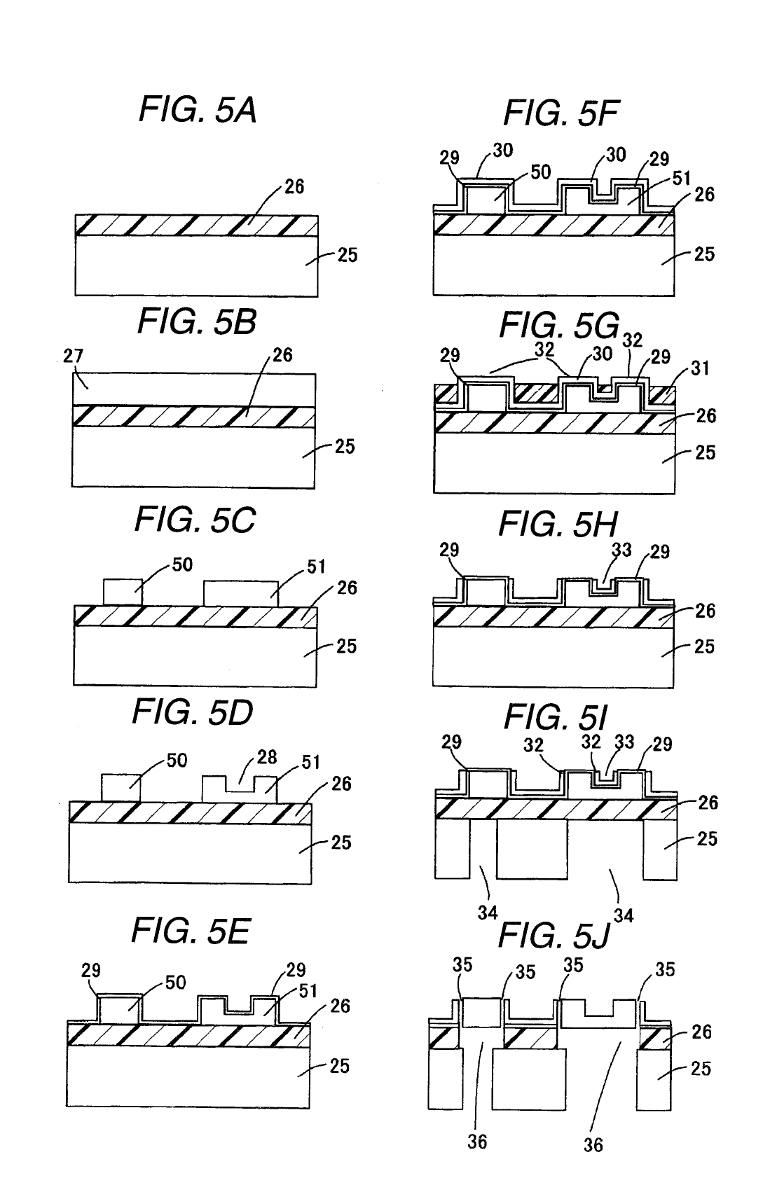

FIGS. 5A to 5J are sectional views showing a manufacturing method according to the third embodiment and an MEMS device manufactured by this method.

The electrode manufacturing method according to this embodiment is characterized in that by making at least one small groove 28 at the apex of a sectional square protrusive portion 51, an area through which resist flows can be assured in an apex plane, thereby completely exposing the upper face of the protrusive portion 51.

In this embodiment, first, as shown in FIG. 5A, an oxide film 26 having 1 μm or more is deposited on a single-crystal silicon substrate 25. Next, as shown in FIG. 5B, a device forming layer 27 of an amorphous silicon layer for making a movable structure is deposited. Further, as shown in FIG. 5C, the device forming layer 27 is patterned to form square protrusive portions 50, 51.

Next, as shown in FIG. 5D, the device forming layer 27 is subjected to the second patterning to form a resist pattern by photolithography. Etching is performed to form a groove 28 in the square protrusive portion 51 by using the resist pattern as a mask. Meanwhile, for example, where the upper face of the protrusive portion has a flat plane with a width of several μms or more, if the step of applying resist and exposing the apex is performed, the resist remains on the upper face of the protrusive portion 51 so that a desired upper face cannot be exposed. In this method, the groove 28 intends to obviate such inconvenience.

Further, in this embodiment, after the groove 28 is formed, as shown in FIG. 5E, the resultant surface is thermally oxidized to form a thin insulating film 29. Further, a conductive film 30 is stacked on the thin insulating film 29.

Further, as shown in FIG. 5G, the device forming layer is subjected to the third patterning to form a mask. In this step also, a resist 31 is applied on the substrate so that the thickness of the resist 31 is thinner than the height of the device forming layer. At this time, the resist deposited on the upper face of the square protrusive portion 51 stays in the groove 28 formed in the step shown in FIG. 5D. For this reason, the upper faces 32 of the square protrusive portions 50, 51 are protruded at only desired areas.

As shown in FIG. 5H, the exposed conductive film 30 is etched. In this case, the upper faces of the square protrusive portions 50, 51 are simultaneously etched by a single step. After the etching, a pattern-separated electrode 33 is formed in the groove 28.

Next, as shown in FIG. 5I, the back surface of the silicon substrate 25 is etched to form deep grooves 34. Thereafter, as shown in FIG. 5J, the protrusive portions 50, 51 are opened (gaps for opening the structures are formed).

For example, by performing wet etching, the substrate 25 can be etched from both sides so that the oxide film 26 and the insulating film 29 can be removed simultaneously. Further, if the insulating film 29 is removed in this step, the electrode 33 formed in the groove 28 is opened so that the electrode does not stay in the groove 28 of the protrusive portion 51. After the etching, gaps 35 are formed and grooves 36 for opening the protrusive portions are formed, thereby completing the hollow structures of the square protrusive portions 50, 51 having the electrodes.

In the above embodiments, although the pattern-separation of the conductive film is explained, the present invention can be applied to not only the pattern-separation of the conductive film but also to the pattern-separation of a thin film such as the insulating film or other functional films.

The manufacturing method of forming electrodes according to the present invention can eliminate the need of a resist etch-back step whose control is difficult and simultaneously execute separation of a convex apex and formation of electrodes easily and precisely, and particularly is useful as the MEMS resonator in an application field of the MEMS.

What is claimed is:

1. A method for manufacturing a semiconductor device comprising:
forming a protrusive portion on a surface of a semiconductor substrate;
forming a thin film on the surfaces of the semiconductor substrate and the protrusive portion;
applying a resist on a surface of the thin film so that at least an apex of the protrusive portion on which the thin film is formed is exposed;
etching the thin film formed on the apex of the protrusive portion which is exposed from the resist to separate a pattern of the thin film into a plurality of patterns of the thin film; and
removing the resist.

2. The method according to claim 1, further comprising:
forming an insulating film on the surface of the protrusive portion,
wherein the protrusive portion has an inclined face;
wherein the thin film is a conductive film; and
wherein the conductive film is formed on the surfaces of the semiconductor substrate and the insulating film formed on the protrusive portion in the forming process of the thin film.

3. The method according to claim 2, wherein the separating process includes:
patterning the resist to expose a part of the conductive film by photolithography process; and
etching the part of the conductive film which is exposed from the resist in the patterning process and an apex part of the conductive film disposed on the apex of the protrusive portion.

4. The method according to claim 2, wherein the semiconductor substrate is an SOI substrate having a single-crystal silicon layer formed on a surface thereof; and
wherein the forming process of the protrusive portion includes a process of forming the protrusive portion by anisotropic etching so that a (111) plane of the SOI substrate is remained as the inclined face.

5. The method according to claim 2, further comprising:
forming an embedded insulating layer (BOX layer) on the surface of the semiconductor substrate prior to the forming process of the protrusive portion; and
removing the insulating layer between the conductive film and the protrusive portion and the embedded insulating layer formed below the protrusive portion.

6. The method according to claim 5, wherein the embedded insulating film is formed so as to have a step portion at an area on which the protrusive portion is to be formed such that the step portion is higher than other area of the surface of the semiconductor substrate.

7. The method according to claim 5, wherein the forming process of the protrusive portion includes:
forming a concave portion on an apex plane of the protrusive portion.

8. The method according to claim 7, wherein the apex plane of the protrusive portion has a flat face.

9. The method according to claim 5, wherein the forming process of the embedded insulating layer includes:
forming a deep groove from a back face of the semiconductor substrate.

10. The method according to claim 2, wherein the insulating film is an oxide film which is formed by oxidation of the semiconductor substrate.

11. The method according to claim 10, wherein the oxide film having a thickness of several nms is formed by a chemical reaction of the surface of the semiconductor substrate in substrate cleaning.

12. A semiconductor device formed by the method for manufacturing the semiconductor device as set forth in claim 1, comprising:
an oscillator which is formed to be mechanically oscillatable;
an electrode which is arranged apart by a predetermined interval from the oscillator,
wherein the oscillator serves as an MEMS resonator configured by the protrusive portion.

13. The semiconductor device according to claim 12, wherein the oscillator has a triangular section.

14. The semiconductor device according to claim 12, wherein the electrode has a step portion.

15. The semiconductor device according to claim 12, wherein the oscillator has a square section.

16. The semiconductor device according to claim 12, wherein the oscillator has at least one groove on an upper face thereof.
